(19) United States
(12) Patent Application Publication
(10) Pub. No.: US 2016/0111556 A1
(43) Pub. Date: Apr. 21, 2016

(54) HIGH TEMPERATURE SOLAR CELL MOUNT

(71) Applicant: Solstice Power LLC, Manlius, NY (US)

(72) Inventors: Griffin M. Kearney, Liverpool, NY (US); James A. Shomar, Manlius, NY (US)

(21) Appl. No.: 14/883,132

(22) Filed: Oct. 14, 2015

Related U.S. Application Data
(60) Provisional application No. 62/234,378, filed on Sep. 29, 2015.
(60) Provisional application No. 62/217,423, filed on Sep. 11, 2015.
(60) Provisional application No. 62/064,290, filed on Oct. 15, 2014.

(51) Int. Cl. H01L 31/02; F16B 1/00; H02S 20/00

(52) U.S. Cl. CPC H01L 31/02008; H02S 20/00; F16B 1/00; F16B 2001/0064

(57) ABSTRACT

A high temperature electro-mechanical pressure mount for a solar cell includes a plate which is electrically insulating and thermally conductive. A center flat strip is disposed on or in the plate front surface. A first flat strip and a second flat strip are disposed on or in the plate front surface on either side of a solar cell foot print area respectively. A first flat lead and a second flat lead are disposed on and about perpendicular to the first flat strip and the second flat strip respectively and mechanically, thermally, and electrically couple respectively to the busbar edges on either side of the solar cell disposed over about a solar cell footprint area and hold the solar cell in the high temperature electro-mechanical pressure mount by a mechanical pressure. A method for mounting a solar cell in a high temperature electro-mechanical pressure mount is also described.

### CROSS-REFERENCE TO RELATED APPLICATIONS

This application claims priority to and the benefit of co-pending U.S. provisional patent application Ser. No. 62/064,290, HIGH TEMPERATURE SOLAR CELL MOUNT, filed Oct. 15, 2014, co-pending U.S. provisional patent application Ser. No. 62/217,423, HIGH TEMPERATURE SOLAR CELL MOUNT, filed Sep. 11, 2015, and co-pending U.S. provisional patent application Ser. No. 62/234,378, HIGH TEMPERATURE SOLAR CELL MOUNT, filed Sep. 29, 2015, which applications are incorporated herein by reference in their entirety.

### FIELD OF THE APPLICATION

The application relates to solar cell mounts and particularly to solar cell mounts for concentrated solar light applications.

### BACKGROUND

The use of solar cells and solar panels as a form of renewable electrical power generation is well-known. As solar cell technologies improve and the cost of solar cell, solar panel, and related electronics fall, solar electrical energy generation is becoming more common as a viable alternative energy source.

### SUMMARY

According to one aspect, a high temperature electro-mechanical pressure mount for a solar cell having a solar cell foot print area, a back surface metallization, and at least two busbar edges on either side of the solar cell includes a plate which is electrically insulating and thermally conductive having a plate front surface and a solar cell foot print area. A center flat strip is disposed on or in the plate front surface at about the solar cell foot print area and extend outwardly from either side of the solar cell foot print area in a flat strip direction. The center flat strip is electrically conductive and thermally coupled to the plate front surface. A first flat strip and a second flat strip are disposed on or in the plate front surface on either side of the solar cell foot print area respectively and extend beyond the solar cell foot print area in the flat strip direction, both of the first flat strip and a second flat strip are thermally and mechanically coupled to the plate front surface. A first flat lead and a second flat lead are disposed on and about perpendicular to the first flat strip and the second flat strip respectively, such that each end of the first flat lead and a second flat lead are mechanically, thermally, and electrically couple respectively to the busbar edges on either side of the solar cell disposed over about a solar cell footprint area and hold the solar cell in the high temperature electro-mechanical pressure mount by a mechanical pressure exerted by the ends of the first flat lead and a second flat lead respectively against the busbar edges on either side of the solar cell.

In one embodiment, the mechanical pressure exerted by the ends of the first flat lead and the second flat lead respectively against the busbar edges on either side of the solar cell comprises a mechanical pressure of about between about 1×10⁶ N/m² and 20,000×10⁶ N/m².

In one embodiment, the first flat strip and the second flat strip are thermally and mechanically coupled to the plate front surface by a thermal epoxy.

In another embodiment, the first flat lead and a second flat lead are thermally and electrically coupled to the first flat strip and the second flat strip by an epoxy.

In another embodiment, the first flat lead and a second flat lead are mechanically coupled to the first flat strip and the second flat strip by a fastener.

In yet another embodiment, the center flat strip is thermally coupled to the plate by a thermal compound or a thermal epoxy.

In yet another embodiment, the thermal compound includes a thermal grease.

In yet another embodiment, at least one of the first flat lead and the second flat lead include an S shape to provide a raised end.

In yet another embodiment, the center flat strip includes at least one or more holes to provide a path within the center flat strip for a gas flow or a fluid flow.

In yet another embodiment, each raised end of the first flat lead and the second flat lead are mechanically, thermally, and electrically coupled respectively to the busbar edges on either side of the solar cell by an electrically conductive thermal grease.

In yet another embodiment, the center flat strip provides a positive electrical terminal of a solar cell, and either or both of the first flat lead and the second flat lead provide a negative terminal of the solar cell.

In yet another embodiment, the first flat strip and the second flat strip include copper.

In yet another embodiment, the first flat lead and the second flat lead include copper.

In yet another embodiment, the first flat lead and the second flat lead include an S bend.

According to another aspect, a high temperature electro-mechanical pressure mount for a solar cell having a solar cell foot print area, a back surface metallization, and at least two busbar edges on either side of the solar cell includes a plate which is electrically insulating and thermally conductive having a plate front surface and a solar cell foot print area. A center flat strip is disposed over the solar cell foot print area and extending outward from either side of the solar cell foot print area in a flat strip direction. The center flat strip is electrically conductive and thermally coupled to the plate front surface by a thermal compound or a thermal epoxy. A first flat strip and a second flat strip are disposed on either side of the solar cell foot print area respectively. Both of the first flat strip and a second flat strip are thermally and mechanically coupled to the plate front surface by a thermal epoxy. A first flat lead and a second flat lead are disposed on and about perpendicular to the first flat strip and a second flat strip respectively. Each raised end of the first flat lead and a second flat lead are mechanically, thermally, and electrically coupled respectively to the busbar edges on either side of the solar cell disposed over about a solar cell footprint area. The first flat lead and second flat lead hold a solar cell back surface metallization of the solar cell in a mechanical and an electrical contact with the center flat strip by an electro-mechanical pressure mount caused by mechanical pressure of each raised end of the first flat lead and a second flat lead mechanically against each of a pair of side busbars of the solar cell respectively. The first flat strip provides a first electrical terminal of the high temperature electro-mechanical pressure mount, the first electrical terminal electrically coupled to the back surface metallization of the solar cell, and the first flat lead and a second flat lead provide a second electrical terminal of the high temperature electro-mechanical pressure mount, the second electrical terminal electrically coupled to at least two busbar edges on either side of the solar cell.

According to yet another aspect, a method of mounting a solar cell in a high temperature electro-mechanical pressure mount including the steps of: providing an electrically insulating and thermally conductive plate having a plate front surface and a solar cell foot print area; mounting a center flat strip, a first strip, and a second strip to the plate front surface, the first strip and the second strip separated from and adjacent to the center flat strip, all of the center flat strip, the first strip, and the second strip oriented in about a flat strip direction on the plate front surface; applying a thermal compound to the center flat strip over about the solar cell foot print area; setting a back surface metallized layer of a solar cell into the thermal compound; applying an electrically conductive thermal compound to at least two busbar edges on either side of a light receiving surface of the solar cell; and mounting mechanically and electrically a first flat lead and a second flat lead over the first strip, and a second strip respectively, each in a direction about perpendicular to the flat strip direction where an end of each flat lead overlaps and couples to each of the busbar edges respectively, by at least in part pressing on the busbar edges through the electrically conductive thermal compound.

In one embodiment, the step of mounting a center flat strip, a first strip, and a second strip includes mounting a center flat strip, a first strip, and a second strip to the plate front surface by use of a thermal epoxy.

In another embodiment, the step of mounting mechanically and electrically a first flat lead and a second flat lead over the first strip includes mounting mechanically and electrically a first flat lead and a second flat lead over the first strip, and a second strip respectively by use of an epoxy.

The foregoing and other aspects, features, and advantages of the application will become more apparent from the following description and from the claims.

### BRIEF DESCRIPTION OF THE DRAWINGS

The features of the application can be better understood with reference to the drawings described below, and the claims. The drawings are not necessarily to scale, emphasis instead generally being placed upon illustrating the principles described herein. In the drawings, like numerals are used to indicate like parts throughout the various views.

FIG. 1 shows an exploded view of an exemplary embodiment of an electrical pressure contact solar cell mount;

FIG. 2 shows an isometric view of an assembled solar cell according to FIG. 1;

FIG. 3A shows an exemplary top plate according to FIG. 1;

FIG. 3B shows an exemplary bottom plate according to FIG. 1;

FIG. 4 shows the top plate of FIG. 3A glued to the bottom plate of FIG. 3B;

FIG. 5 shows an exemplary central region of the solar cell mount of FIG. 1;

FIG. 6 shows an exemplary photovoltaic array of solar cell mounts, each solar cell of each mount at about a focal length from a concentrating optical lens;

FIG. 7 shows a block diagram of one exemplary lens solar cell combination; and

FIG. 8 shows a flow diagram of an exemplary method to manufacture a high temperature solar cell mount;

FIG. 9A is a drawing showing a side view of an exemplary high temperature solar cell mount without a top plate;

FIG. 9B is a drawing a top view of the high temperature solar cell mount without a top plate of FIG. 9A;

FIG. 9C is a drawing an end view of the high temperature solar cell mount without a top plate;

FIG. 9D is a drawing showing an isometric view of an assembled high temperature solar cell mount without a top plate;

FIG. 9E is a detailed drawing A as referenced by FIG. 9A;

FIG. 10 shows an exploded view of exemplary parts suitable to make a high temperature solar cell mount without a top plate;

FIG. 11A shows a drawing of side view of a of a high temperature solar cell mount;

FIG. 11B shows a top view of the assembly of FIG. 11A;

FIG. 11C shows a side view of the assembly of FIG. 11A;

FIG. 11D is an isometric drawing of the assembly of FIG. 11A;

FIG. 12A shows an exemplary exploded view of a of a high temperature solar cell mount;

FIG. 12B shows a partially exploded view of the high temperature solar cell mount of FIG. 12A; and

FIG. 12C shows an isometric view of the high temperature solar cell mount of FIG. 12A;

FIG. 13 shows an isometric view of an exemplary high temperature solar cell mount with flat strips;

FIG. 14A shows a side view of the solar cell mount of FIG. 13;

FIG. 14B shows a partial section view of the solar cell mount of FIG. 14A;

FIG. 15 shows an end view of the solar cell mount of FIG. 14A; and

FIG. 16 shows a magnified view of a portion of the side view of FIG. 14A;

FIG. 17A shows an isometric view of an exemplary high temperature solar cell mount with flat strips embedded in the plate;

FIG. 17B shows a side view of the solar cell mount of FIG. 17A;

FIG. 18A shows an exemplary embodiment of a high temperature solar cell mount with flat strips with holes for a cooling gas or fluid to flow through the flat center strip;

FIG. 18B shows a partial magnified view of the high temperature mount of FIG. 18A;

FIG. 18C shows a side view of the high temperature mount of FIG. 18A;

FIG. 19A shows an isometric view of an exemplary high temperature mount where the flat leads are coupled to the flat strips by a fastener; and

FIG. 19B shows a side view of the high temperature mount of FIG. 19A.

### DETAILED DESCRIPTION

As discussed hereinabove, as solar cell technologies improve and solar cell, solar panel, and the cost of related electronics fall, solar electrical energy generation is becoming more common as a viable alternative energy source. Some of the improvements involve improvements in the composition and construction of the solar cells themselves. For example, some emerging solar cell technologies make more efficient use of a wider portion of the solar spectra. Other new technologies offer improvements in conversion efficiency, such as by use of new materials and/or new methods of solar cell manufacture.

Another approach for improving conversion efficiency uses one or more lenses to focus light from a collection area (e.g. the surface area of a lens) to a smaller area solar cell (e.g. concentrated photovoltaics). Unfortunately, such approaches have been limited by a corresponding heat rise of the solar cell. Excessive heat can cause high temperatures which can reduce efficiency of the solar cell and damage the solar cell material and related connection components. Such heat damage can reduce the useful life of a concentrated light solar system so that there is an insufficient useful working life before a system failure. Or, a concentrated light solar cell can be intentionally operated well below optimized optical and electrical efficiency point to keep the heat rise to manageable levels, accepting the loss in power conversion efficiency.

Also, traditional solar cell mount construction has relied on soldering (e.g. vacuum formed soldering to guard against voids for high temperature applications such as in concentrated photovoltaics) to connect individual solar cells to make arrays of solar cells. For higher temperature applications, some specialized welding techniques, such as vacuum forming have been used.

There is a need for a cost efficient solar cell mount that can efficiently remove waste heat from a solar cell to allow it to be operated closer to optimized levels of light concentration. There is also a need for simpler cost effective way to form electrical connections to a solar cell.

Applicants realized that a pressure contact can be used without need for direct soldering or welding to the surfaces of the solar cell itself.

Also, as now described in more detail hereinbelow, the electrical pressure contacts are cost effective and can be manufactured in mass production at relatively low cost compared with conventional soldering techniques as well as specialized welding techniques.

Several specific embodiments of a new type of pressure or interference fit high temperature solar cell mount are shown in the drawings and described in detail hereinbelow. The present disclosure is understood and to be considered as an exemplification of the principles of the various embodiments of the pressure or interference fit high temperature solar cell mount and is not intended to limit the scope of the claims to the specific exemplary embodiments illustrated herein.

The new solar cell mount uses high thermal conductivity ceramic or metallic plates to mount a solar cell, typically a high efficiency photovoltaic (PV) cell which can be used for concentrated solar energy collection. Any suitable solar cell can be used. The plates are electrically insulating, that is, not electrically conductive. Metallic materials are electrically conductive to provide leads by electrical pressure contacts at the appropriate areas of a solar cell to facilitate the harnessing of electrical energy. A thermal compound, such as, for example a thermal gel, or thermal grease is used to provide and maintain the thermal transfer integrity of the system. Industrial adhesives are used to provide the structural integrity of the mount. Also, the new mount can be mechanically coupled to a metal surface, such as, for example, by machine bolts, to further provide for heat flow from the solar cell mount into another heat sink on which the solar cell mount is bolted to.

High Temperature Solar Cell Mount with Top Plate

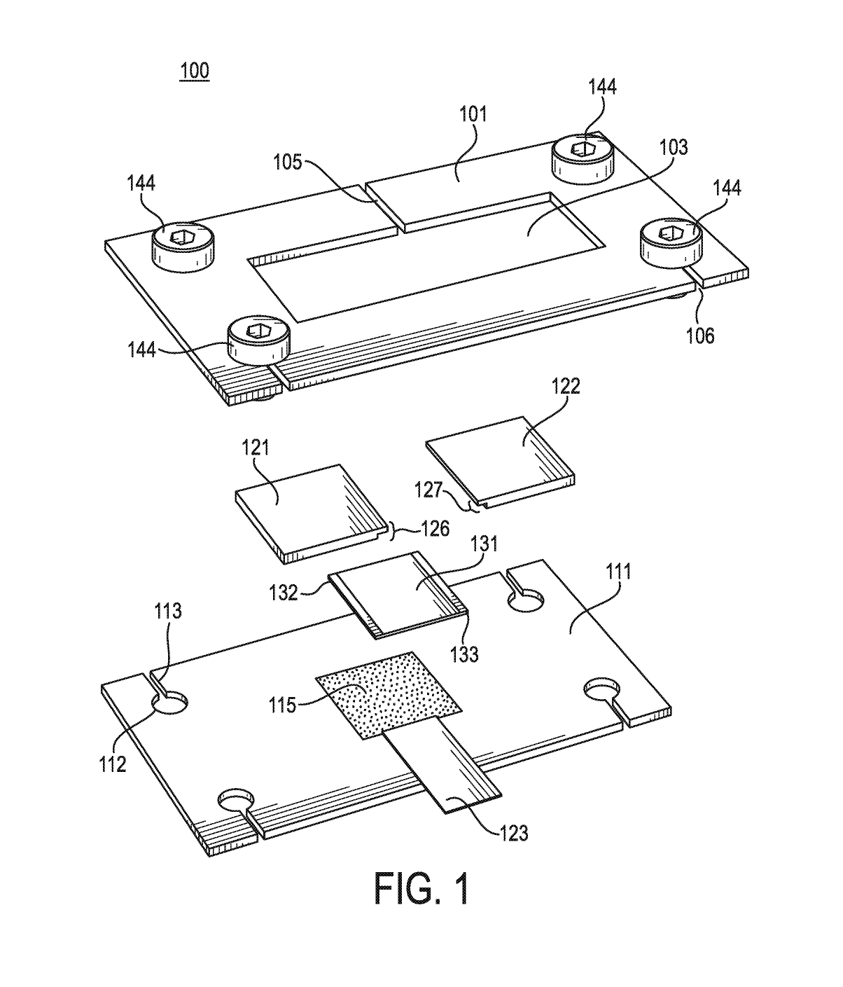

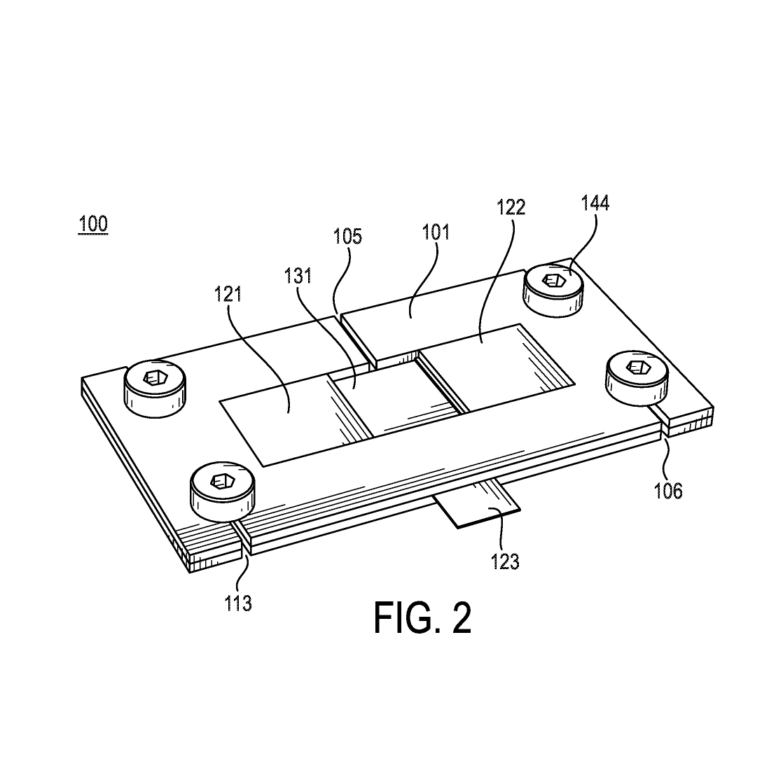

FIG. 1 shows an exploded view of an exemplary embodiment of the new electrical pressure contact solar cell mount 100. FIG. 2 shows an isometric view of an assembled solar cell according to FIG. 1. A conductor, such as, for example, flat wire 123 makes an electrical pressure contact with the back surface of the solar cell 131, typically a metallized surface serving as the positive terminal of the solar cell 131. Flat wire 123 can be manufactured from any suitable metal, preferably having both good electrical conductivity and good thermal conductivity. Copper is an example of a suitable metal. Flat wire is available as a commercially manufactured wire type.

Metal block 121 and metal block 122 make electrical pressure contact with top surface electrical contacts of solar cell 131 via fingers or ledges 126, 127. In the exemplary solar cell mount of FIG. 1 and FIG. 2, the negative terminal of solar cell 131 extends to solar cell electrical contract strip 132 (the side busbars of solar cell 131) and solar cell electrical contact strip 133. Metal block 121 and metal block 122 have corresponding fingers or ledges 126, 127, such as, for example, a machined ridge which holds solar cell 131 down against flat wire 123 an provides the opposite electrical terminal connection to the solar cell. In the exemplary embodiment of FIG. 1 and FIG. 2, the strips of metallized busbar on the solar cell in pressure contact with the fingers or ledges 126, 127 of metal blocks 121 and 122 provide the negative solar cell terminal. Metal block 121 and metal block 122 can be machined from any suitable metal, preferably having both good electrical conductivity and good thermal conductivity. Copper is an example of one such suitable metal.

Heat transfer from the solar cell can be provided both through metal block 121, metal block 122, and flat wire 123, and by contact of the solar cell via a thermal compound 115, such as for example, a thermal grease or a thermal gel, with a bottom plate 111. As described hereinbelow, the thermal compound 115 can be applied according to a novel method which prevents thermal compound from being applied between the flat surface of flat wire 123 and the back surface 134 of solar cell 131 which might otherwise interfere with the electrical conductivity of the pressure contact with the metallization on the back surface 134 of solar cell 131. There can also be useful heat flow from metal block 121 and metal block 122 to top plate 101. Bottom plate 111 and top plate 101 are made from an electrically insulating material with high thermal conductivity. Exemplary materials include ceramics, such as, for example, aluminum nitride.

In the exemplary embodiment of FIG. 1 and FIG. 2, slots 105, 106, and 113 are artifacts of a standard water cutting method. Where the plates are cut by methods other than water jet cutting, there can be embodiments of the plates with no slots. Also, it may be desirable to introduce one or more slots for feed through or pass through applications, such as, for example passing one or more conductor to or from the central region. In other applications, there may be other applications for pass through, such as, for example, fluid pipes related to thermal management.

### Example

An exemplary embodiment of the new electrical pressure contact solar cell mount has been built and tested. The top and bottom plates were cut from sheets of Aluminum Nitride. Each of the sheets were about 0.04 inches thick. The sheets are model no. AN-170 available from the Maruwa America Corp. Santa Ana, Calif. The sheets were cut to the desired pattern similar to top plate 101 and bottom plate 111 of FIG. 1 using a water jet cutting method well-known in the art. The top and bottom plates were about 2 inches long×one inch wide.

The exemplary mount solar cell assembly used a C3MJ concentrator solar cell from SPECTROLAB™ of Sylmar, Calif. The grid fingers of the C3MJ concentrator solar cell are electrically coupled as part of the solar cell to strips of silver metallization formed as two busbars on the light side of the solar cell (shown as solar cell electrical contract strips 132 and 133 in FIG. 1). The prototype ledges or fingers 126, 127 of the metal blocks 121 and 122 were cut with a Dremel™ tool so as to both hold the solar cell in the mount as well as to provide electrical contact to the two solar cell busbar strips. The metal blocks were about one square cm area and about 2 mm thick. The dimensions of the fingers or ledge were about 1 mm wide. Any suitable form of machining can be used to machine flat metal stock to have ledges or fingers suitable to hold various types of solar cells. The flat wire used was about 100 microns thick and about 5 mm wide. The thermal compound used was Antec, formula 7 nano diamond thermal compound, available from Freemont, Calif. The electrical pressure contact solar cell mount was assembled using the assembly technique described hereinbelow using J-B Weld adhesive available from J-B Weld.

Assembly Method:

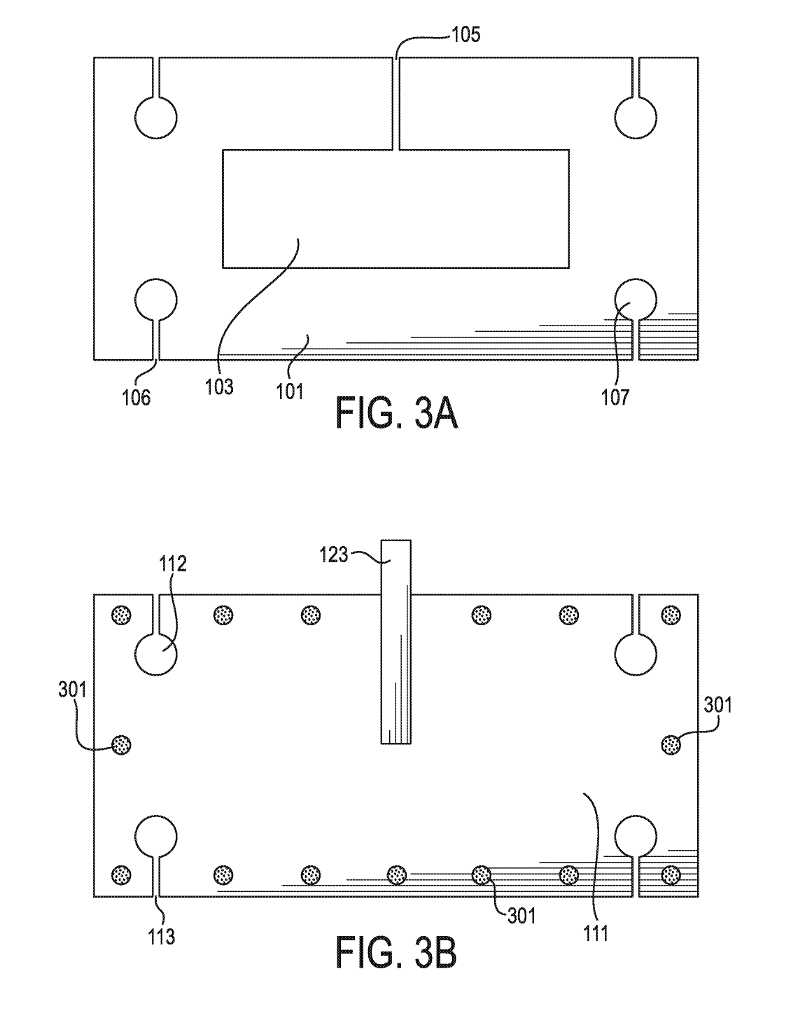

FIG. 3A shows one exemplary top plate cut to a desired pattern by a water jet cutting technique as is well-known in the art. Any suitable cutting means (e.g. diamond cutting) can be used. Using a water jet cutting technique, there may be slots created as the cutter or cutting stream (e.g. a water jet) follow a cutting pattern. For example, in FIG. 3A, slot 105 results from the exemplary cutting means entering the center region to cut out the center region opening 103 where the solar call and metal blocks will later be placed. Similarly, slots 106 are the result of cutting mounting holes 107.

FIG. 3B shows one exemplary bottom plate cut to a desired pattern also by the water jet cutting technique. Slots 112, as explained hereinabove, result from cutting mounting holes 112.

The steps for one exemplary assembly method include, fix the top plate to bottom plate using adhesive, such as, for example, adhesive beads 301, and place the flat wire 123 before sandwiching the top plate to the bottom plate. As described hereinabove, the top plate and the bottom plate are made of a thermally conductive/electrically insulating material. In some embodiments of the assembly method, small adhesive beads 301 can be placed periodically on the bottom plate on which the top plate will be placed. It is preferable that the adhesive be distributed on the bottom plate so that excessive adhesive does not flow out into the central rectangular hole of the top plate when the two are pressed together. In the event of excessive adhesive entering the center cut out region, it should be removed by any suitable mechanical and/or solvent means. Pressure can be applied to hold the top plate to the bottom plate to keep the two plates flush and aligned while the adhesive sets. The flat wire, or any other suitable conductor, can be held in place by the pinching actions of the upper and lower plates.

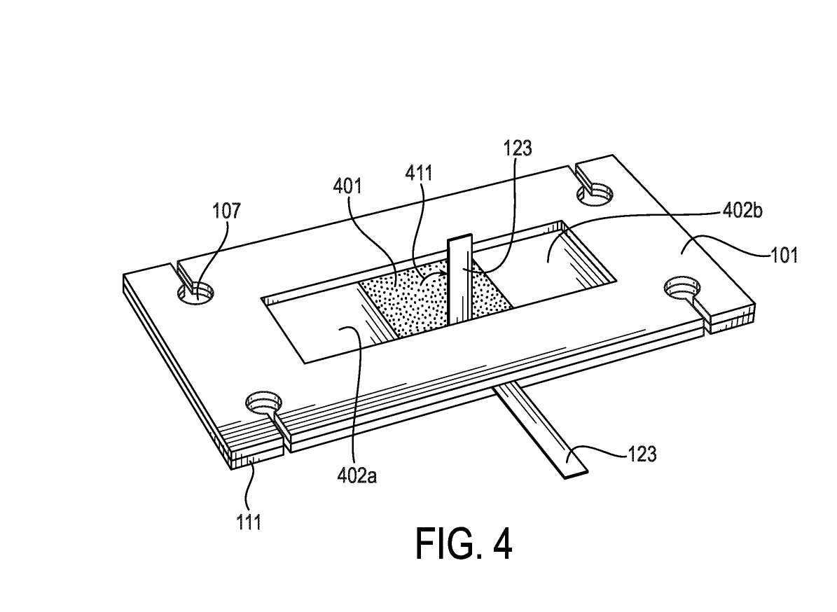

FIG. 4 shows the top plate now glued to the bottom plate and how the flat wire (or, any other suitable conductor having any suitable geometric form and/or dimensions) in the opening in the central region can be bent away from the bottom plate (e.g. arrow 411) so that the top surface of the flat wire which later becomes the electrical pressure contact to the rear terminal of the solar cell, remains substantially clean and free of adhesive or thermal compound during successive assembly steps. The length of flat wire now present in the upper plate's rectangular cut is bent upward and out, away from the opening in the central region. Thermal compound 115, such as, for example, a thermal gel is placed thinly in the center of the opening in a first portion 401 of the central region (“placed thinly” is defined herein as thinner than the thickness of the flat wire) in the rectangular cut out, leaving room on the sides of the cut out for adhesive later. There should be enough thermal compound to cover the bottom of the solar cell when it is placed, however not so much so as to interfere with the electrical pressure contact between the back side of the solar cell and the flat wire. That is, the thermal compound should not present a layer thicker than the height of the flat wire. The thermal compound is also not applied on either side of a first portion 401 of the central region, where a second portion 402a and a third portion 402b of the central region remains free of thermal compound so as to later accept an adhesive. The second portion 402a and a third portion 402b of the central region are used to affix metal block 121 and metal bock 122 to the first plate 111 as described in more detail hereinbelow.

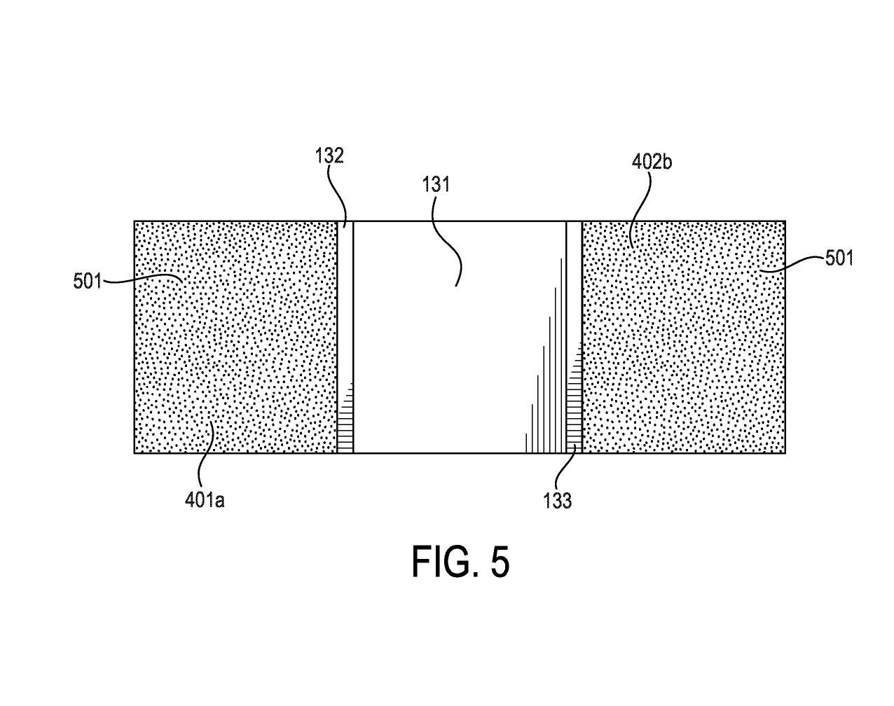

FIG. 5 shows an exemplary central region with solar cell 131 located at the first portion between the second and third portions of the central region. The extra spaces, second portion 402a and third portion 402b on the sides of the now placed solar cell 131 are filled with adhesive 501. Since these are relatively small spaces, we found that the adhesive can be applied efficiently without overflow by measuring the volume and then applying it by any suitable means, such as, for example by syringe to the spaces to either side of where the thermal compound was previously placed. It is contemplated that in production, other methods more efficient than application by syringe, including any other suitable adhesive application methods, such as, adhesive application by volume can be used. Once the adhesive is in place, the electrically conductive metal plates (cut to the size of the rectangular cut out) can be pressed down onto the adhesive and the leads on the sides of the solar cell. The ledges or fingers of the metal blocks should be free of adhesive overflow and maintain good contact with the leads of solar cell for good electrical connectivity with the side busbars of the solar cell. The adhesive needs should be carefully placed (e.g. by volume measurements) so that it does not overflow between the cell leads and the plate interface. Excess adhesive can be removed by any suitable mechanical and/or solvent means.

Once the adhesive cures, the pressure from the metal leads on the sides of the solar cell hold it in place once the adhesive cures.

Applications:

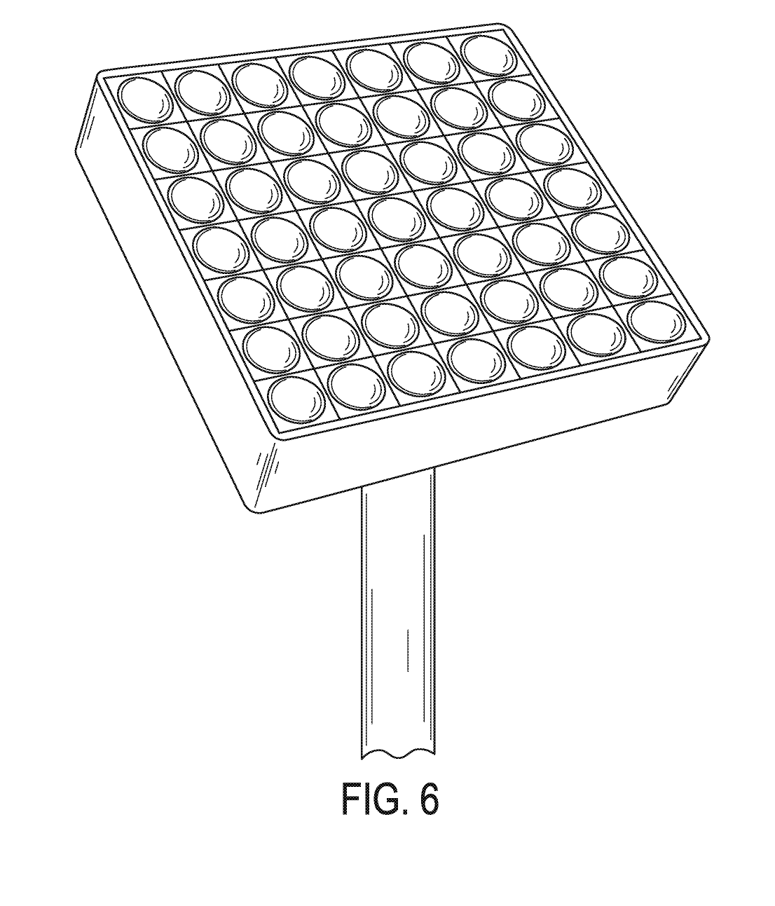

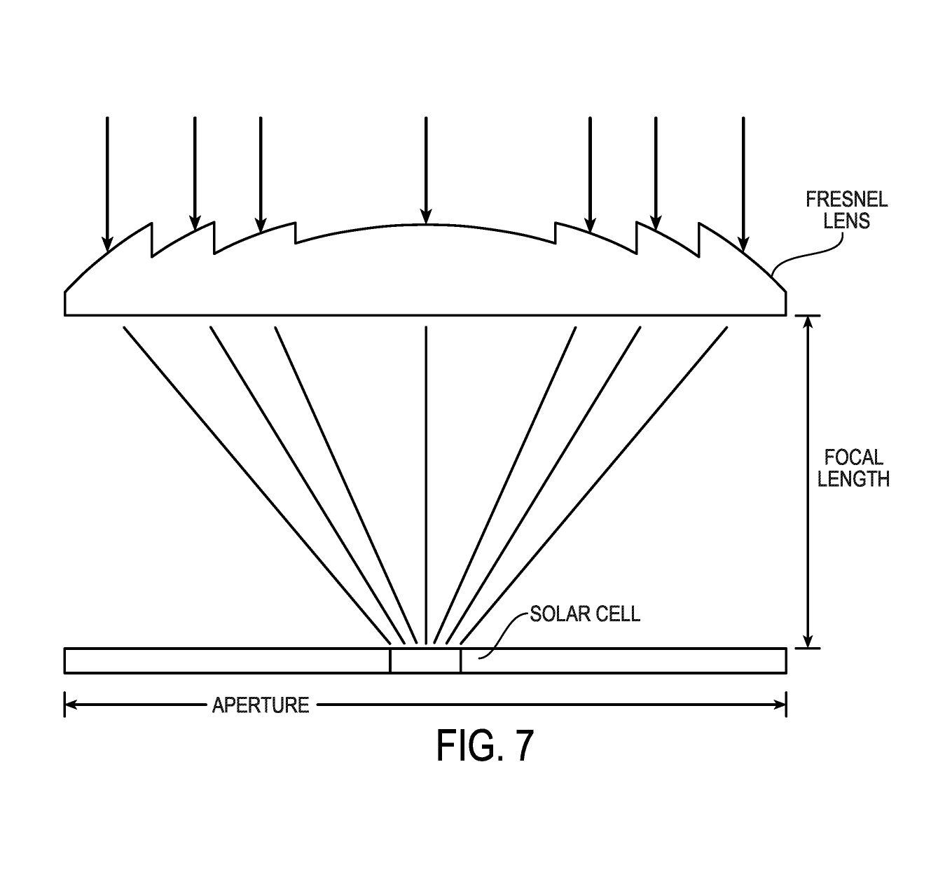

FIG. 6 shows a photovoltaic array using an array of the new electrical pressure contact solar cell mounts, each solar cell of each mount under a concentrating optical lens. FIG. 7 shows a block diagram of one exemplary lens cell combination. In the exemplary embodiment of FIG. 7, a Fresnel lens focuses incoming solar radiation onto the solar cell of an electrical pressure contact solar cell mount as described hereinabove. Any suitable concentrating technology can be used. Also, where one or more concentrating optical lenses are used per solar cell, any suitable optical lens can be used. The Fresnel lens of FIG. 7 is merely representative of one embodiment of a solar concentration system using the electrical pressure contact solar cell mount as described hereinabove.

Now in summary and with reference to the exemplary embodiments of the drawings only to better understand the terms while not limiting to any one specific exemplary embodiment, a high temperature mount for a solar cell 131 includes a first plate 111 and a second plate 101. Both of the first and second plates are electrically insulating and thermally conductive. The second plate 101 has a central cut-out section 103 defining a central region (FIG. 4, 402a, 401, 402b) of the first plate 111. The first plate 111 is mechanically coupled to the second plate 101. A flat wire 123 passes between the first plate 111 and the second plate 101 from outside of the mount to a first portion 401 of the central region of the first plate 111. The flat wire 123 is adapted to make an electrical pressure contact with a back surface metallization of a solar cell 131 and to provide a first electrical contact to the solar cell 131. A thermal compound layer 115 overlays the first portion 401 of the central region of the first plate 111 and surrounds without overlaying the flat wire 123. A height of the thermal compound layer 115 is less than a thickness of the flat wire 123. The high temperature mount for a solar cell 131 also includes a first metal block 121 and a second metal block 122. Both blocks 121, 122 include one edge with a ledge or a finger 126, 127 adapted to hold a busbar edge of a solar cell 131 to provide a second electrical terminal to the solar cell 131. A second portion and a third portion of the central region are located on either side of the first portion 401 of the central region. The second 402a and third 402b portions of the central region of the first plate 111 are mechanically coupled to the first block and the second block to the first plate 111 respectively and adapted to mechanically affix the solar cell 131 to the mount.

One or more conductors or one or more blocks, circles, cylinders, triangles, or any other suitable geometric shaped conductor in place of the two metal blocks of the exemplary embodiment: In other embodiments, there can be only one conductor (e.g. one conductive strip under the top plate, or one block with an opening for the solar cell which makes the electrical contact to one or more electrical terminals on the top (light receiving surface) surface of the solar cell. Therefore, in place of the two metal blocks of the example, one or more conductors can be alternatively substituted for the one or two metal blocks.

The plates can be made from aluminum nitride. A material such as beryllium oxide can also work well, however can be hazardous to machine. Alumina can work, however alumina has less thermal conductivity, and therefore might be used with less solar concentration for thermal heating concerns.

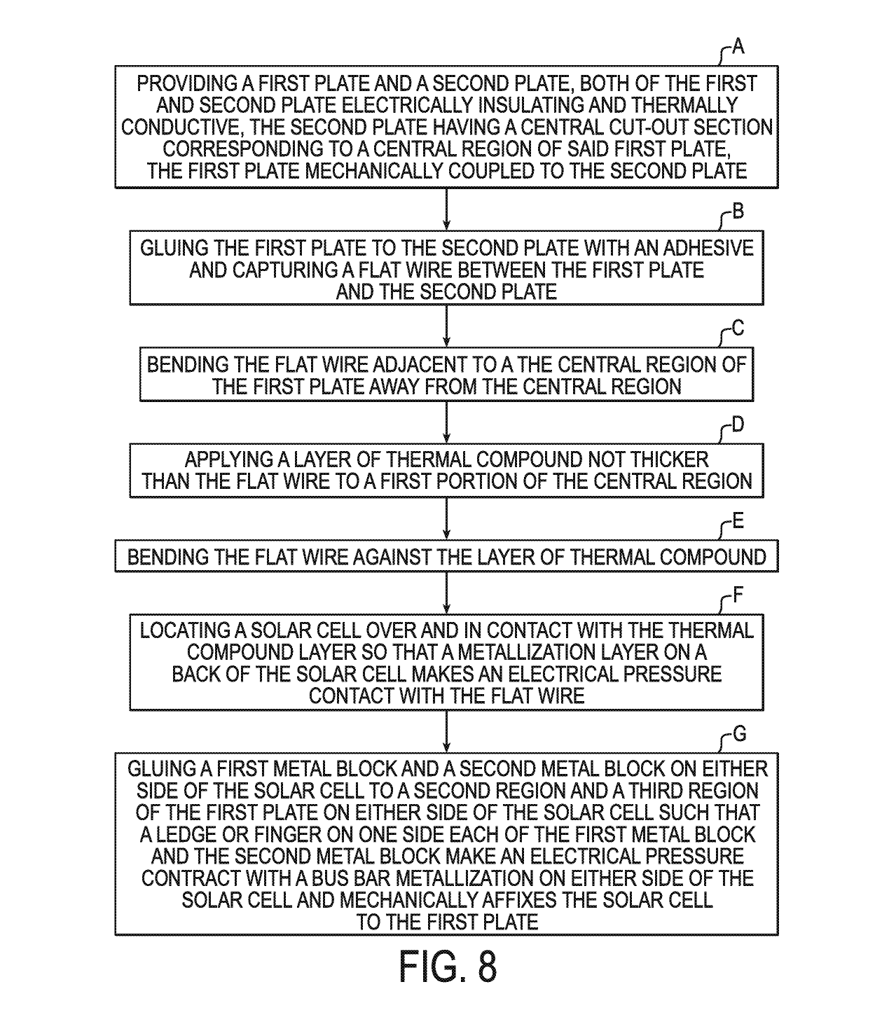

FIG. 8 shows a flow diagram of one exemplary method to manufacture a high temperature solar cell mount comprising: A) providing a first plate and a second plate, both of the first and second plate electrically insulating and thermally conductive, the second plate having central cut-out section corresponding to a central region of the first plate, the first plate mechanically coupled to the second plate; B) gluing the first plate to the second plate with an adhesive and capturing a conductor between the first plate and the second plate; C) bending the conductor adjacent to a the central region of the first plate away from the central region; D) applying a layer of thermal compound not thicker than the conductor to a first portion of the central region; E) bending the conductor against the layer of thermal compound; F) locating a solar cell over and in contact with the thermal compound layer so that a metallization layer on a back of the solar cell makes an electrical pressure contact with the conductor; and G) gluing a first metal block and a second metal block on either side of the solar cell to a second region and a third region of the first plate on either side of the solar cell such that a ledge or finger on one side each of the first metal block and the second metal block make an electrical pressure contract with a busbar metallization on either side of the solar cell and mechanically affixes the solar cell to the first plate.

It is understood that electrical connections can be made to electrical conduction surfaces, electrical conductors, and/or wires of the solar cell mount using any suitable connection means such as soldering, welding, conductive epoxy, and/or additional pressure contacts.

High Temperature Solar Cell Mount without a Top Plate

Removal of Upper Framing Plate: In another embodiment, an upper ceramic or metallic plate is no longer used to hold the components in place during operation. However, in some embodiments, a similar upper plate with central cut can be used temporarily in the manufacture of the high temperature solar cell mount assembly. There are at least two improvements in this new manufacturing method for a high temperature solar cell mount without a top plate: 1) The new method provides a 50% cost reduction in regards to the ceramic or metal used for the plates, and 2) eliminates a component (the original top plate) which could allow for thermal build up.

Substitution of Industrial Epoxy for Two-Sided Laminate Adhesive:

In some embodiments of the high temperature solar cell mount without a top plate, the mount assembly design no longer uses industrial epoxy to hold its components together. Because in such embodiments we no longer use an upper plate with central cut out during operation of the solar cell, we no longer need to fix it to the base plate with a relatively expensive epoxy. Also, in some embodiments, the copper block leads which provide the mechanical pressure for the mechanical pressure fit which holds the energy generating cell to the mount, can be affixed to the bottom plate with a two sided industrial laminate adhesive. The laminate adhesive is used as an industrial grade two-sided tape. However, any suitable adhesive can be used, such as any suitable two sided industrial laminate adhesive. One example of a suitable industrial laminate adhesive is the model no. 100MP available from 3M Corporation of Paul Minn. Each side of the adhesive is initially typically covered with a material which, once removed, exposes the sticky adhesive surface. This allows the laminate to be affixed to the first the base plate or lower plate, and then once it is in place the other covering can be removed (e.g. a peel away protective strip layer) to affix the copper block lead to the upper adhesive face of the adhesive laminate.

Optimizing Electrical Connection of Copper Leads to Cell with Electric Gel:

An electric gel can be optionally used to between the copper block leads and the upper busbar edges of the solar cell. For example, when fixing the copper block leads onto the laminate adhesive and thus forming the pressure fit which maintains the solar cell's position, the notched surface of the copper lead can be coated or “primed” with an electrically conductive gel. The optional gel helps to maintain the electrical connection between the copper block leads and the solar cell's upper electrically charged surfaces. Any suitable conductive gel can be used. One example of a suitable conductive gel is the part number 846-80G conductive gel, available from MG Chemicals of Ontario, Canada.

### Example

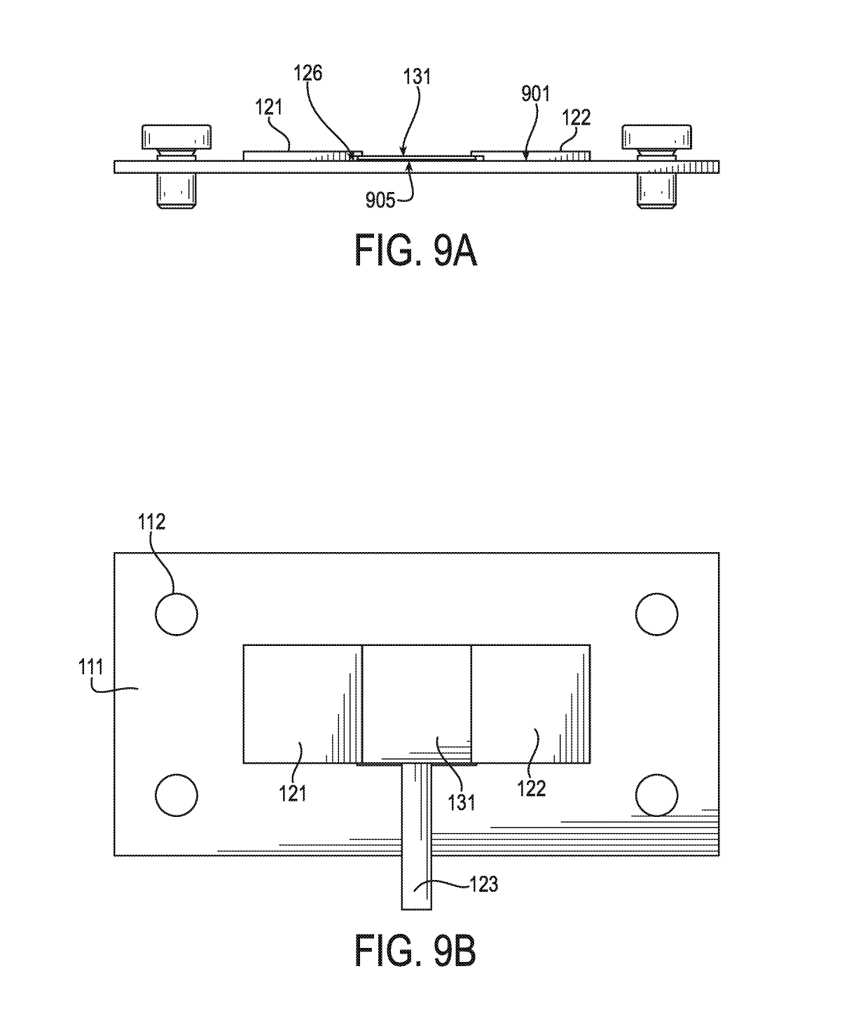

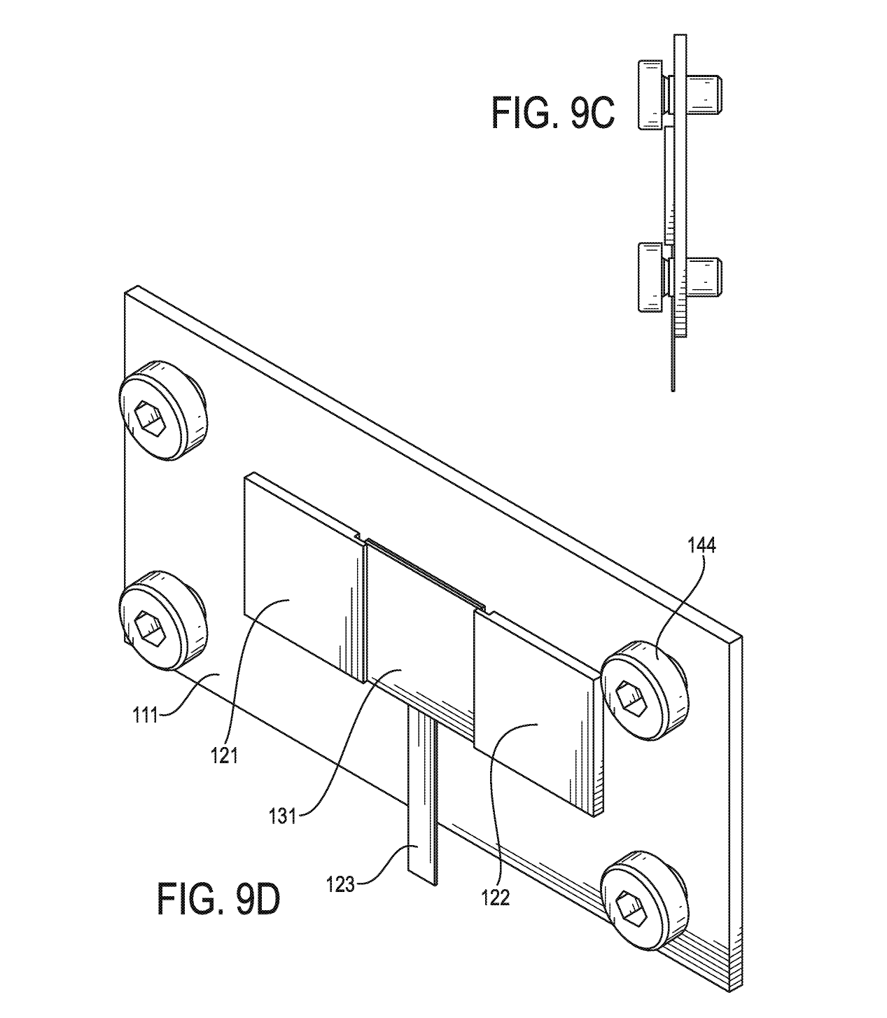

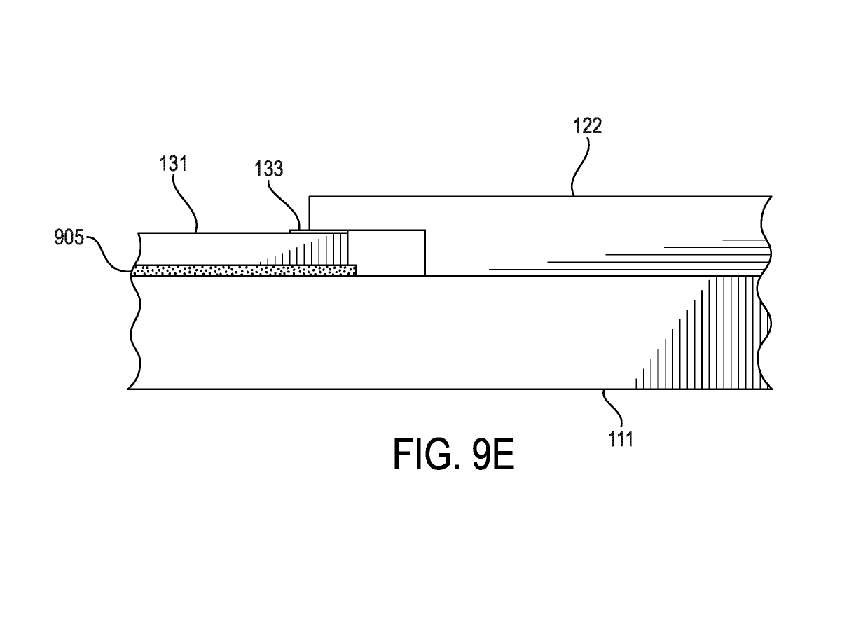

FIG. 9A shows a side view of a high temperature solar cell mount without a top plate. Similar to the embodiments described hereinabove, there is a central portion there is a first portion (central area) (FIG. 4, 401) of the central region which is later covered by a thermal compound 905 and flat wire 123 (thermal compound 905 surrounds, without overlaying flat wire 123), and on either side, a second portion (FIG. 4, 402a) and a third portion (FIG. 4, 402b) of the central region remains free of thermal compound so as to later accept an adhesive (e.g. a laminate adhesive as described in more detail hereinbelow).

The mount accepts a solar cell held onto a bottom plate 111 (a first plate) by metal block 121 and metal block 122. Metal block 121 and metal block 122 are affixed to second portion (FIG. 4, 402a) and a third portion (FIG. 4, 402b) of the central region by an adhesive, such as, for example, an adhesive laminate. Also, as described hereinabove, metal block 121 and metal block 122 make electrical pressure contact with top surface electrical contacts of solar cell 131 via fingers or ledges 126, 127. A first terminal of solar cell 131 (typically the negative terminal) extends to solar cell electrical contract strip 132 and solar cell electrical contact strip 133. Metal block 121 and metal block 122 have corresponding fingers or ledges 126, 127, such as, for example, a machined ridge which holds solar cell 131 down against flat wire 123 an provides the opposite electrical terminal connection to the solar cell. The strips of metallized busbar on the solar cell in pressure contact with the fingers or ledges 126, 127 of metal blocks 121 and 122 provide the negative solar cell terminal. Metal block 121 and metal block 122 can be machined from any suitable metal, preferably having both good electrical conductivity and good thermal conductivity.

Any suitable adhesive, glue or epoxy can be used to affix metal block 121 and metal block 122 to bottom plate 111. In some embodiments, it was realized that a strong efficient and cost effective means to attach metal block 121 and metal block 122 to bottom plate 111 is any suitable two sided industrial laminate adhesive. For example, in some implementations of the mount of FIG. 9A, Tesa™ Model 4965 transparent double-sided self-adhesive tape was used.

FIG. 9B shows a top view of the high temperature solar cell mount without a top plate. FIG. 9C shows an end view of a high temperature solar cell mount without a top plate. FIG. 9D is a drawing showing an isometric view of an assembled high temperature solar cell mount without a top plate. FIG. 9E is a detailed drawing A as referenced by FIG. 9A.

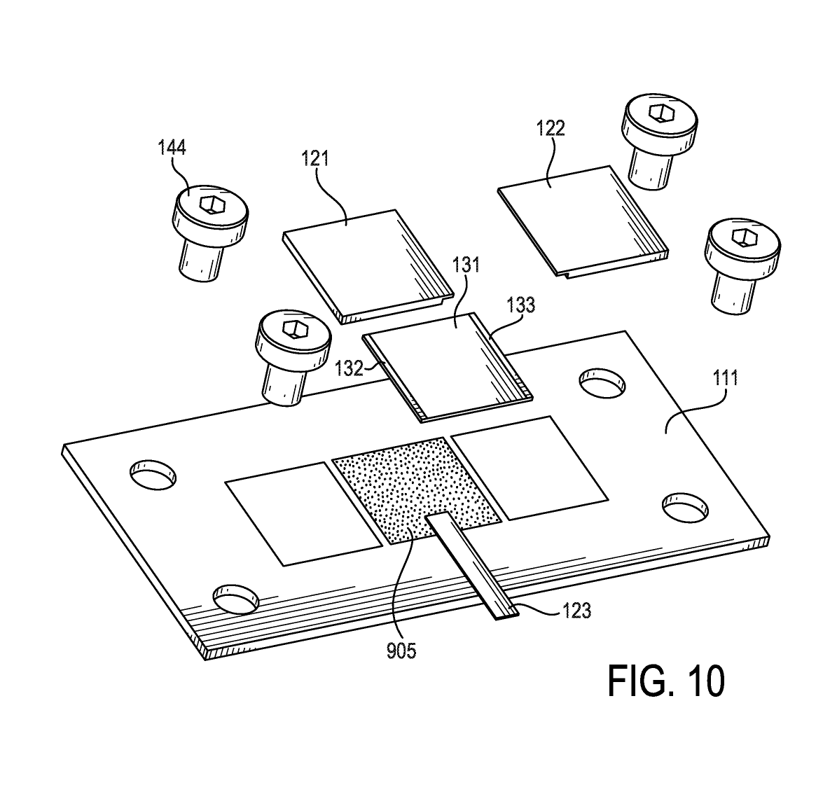

FIG. 10 shows an exploded view of exemplary parts suitable to make a high temperature solar cell mount without a top plate. The overlap between flat wire 123 and the back surface of the solar cell 131 as an electrical pressure contact provides a suitable low resistance connection. The exact amount of overlap is unimportant as long as the contact surface is large enough such that the contact resistance is low enough to prevent unnecessary excessive ohmic heating (power loss by heating at the contact). While electrical pressure contact areas can be as small as 1 nm, typical working contact areas for the embodiments described herein range from about 0.01 square centimeters to about 1 square centimeter. Especially high current applications could use working contact areas up to or beyond about 10 square cm. Thermal compound layer 905 overlays the central area of the central region of the first plate and surrounds without overlaying the conductor flat wire 123.

Manufacturing Technique for a High Temperature Solar Cell Mount without a Top Plate

Using the Upper Framing Plate as a Template:

To maintain the accuracy of the positioning of the various components of a high temperature solar cell mount without a top plate as described hereinabove, a top template plate 1101 (similar in shape to top plate 101 described hereinabove) can be used during assembly. Because the top template plate 1101 is temporary and only used during assembly, the top template plate 1101 can be made using any suitable relatively rigid material. There are no longer any electrical or thermal parameters of particular significance because in this embodiment without a top plate, template is removed during manufacture and no longer used in operation of the high temperature solar cell mount without a top plate. Therefore, top template plate 1101 no longer needs to have any particular electrical and/or thermal characteristics.

In assembly of embodiments of the high temperature solar cell mount without a top plate, the top template plate 1101 is mounted to the base plate as a stencil having central cut out (similar to the central cut-out of top plate 101). The template can have any suitable form with any suitable openings and cutouts. The template can be made from any suitable material which is strong enough to hold components in place during assembly of a high temperature solar cell mount without a top plate. Any material with a suitable rigidity can be used. One exemplary suitable material for a template includes aluminum.

Note that a template is not intrinsically needed for construction of a high temperature solar cell mount without a top plate. Any suitable mechanism, manufacturing apparatus or method which allows for the accurate positioning of the component parts which positions the component parts in the correct places on the bottom plate and/or holds the component parts in place until the adhesive, glue, epoxy, etc. dry or sets up, can be used.

### Example

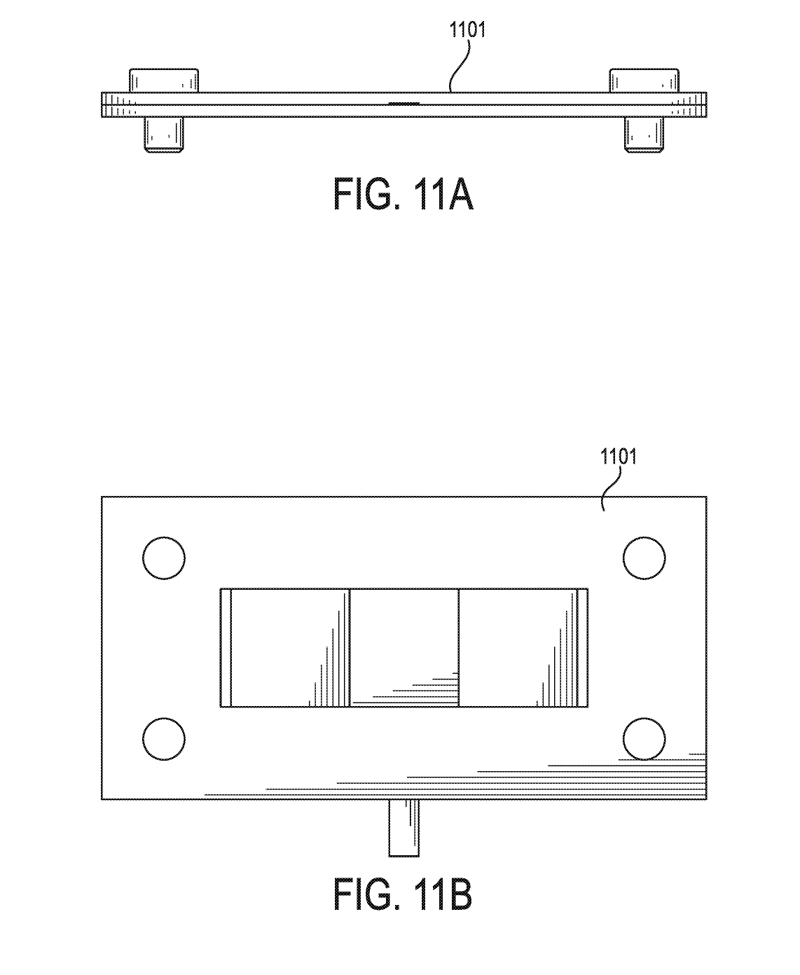

FIG. 11A shows a drawing of side view of a of a high temperature solar cell mount having temporarily installed a top template plate 1101 as an assembly template. FIG. 11B is a drawing showing a top view of the assembly of FIG. 11A. FIG. 11C is a drawing showing a side view of the assembly of FIG. 11A. FIG. 11D is an isometric drawing showing a side view of the assembly of FIG. 11A.

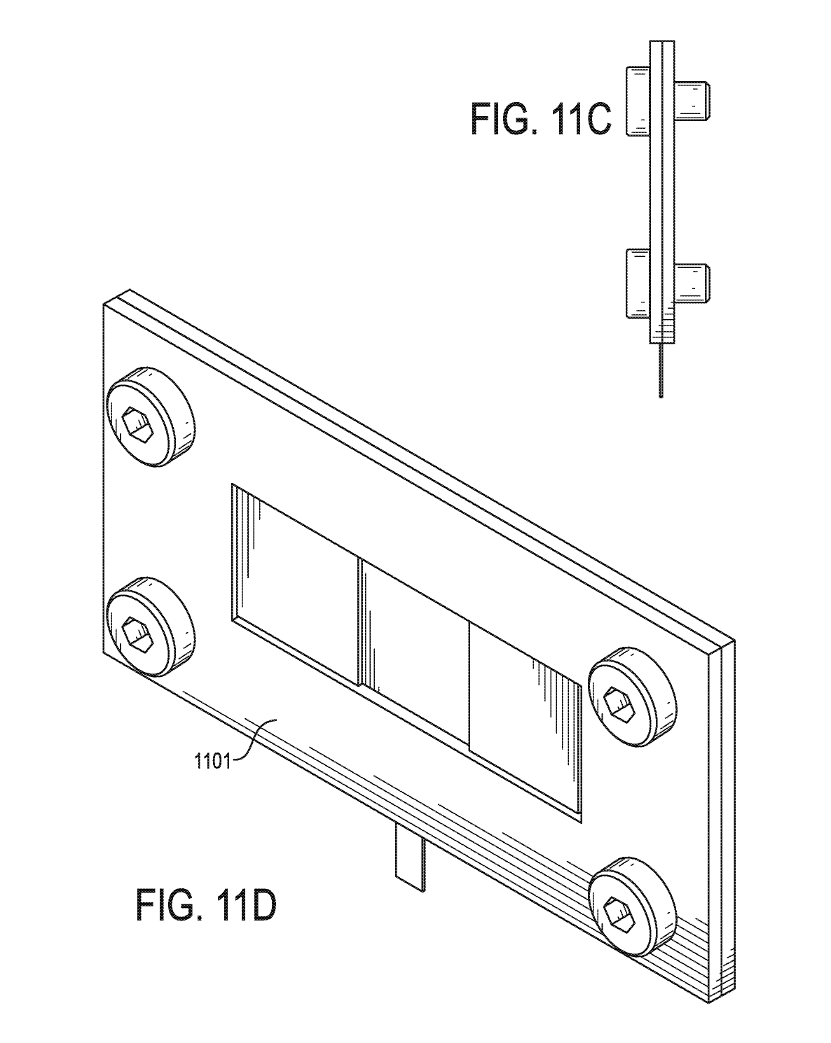

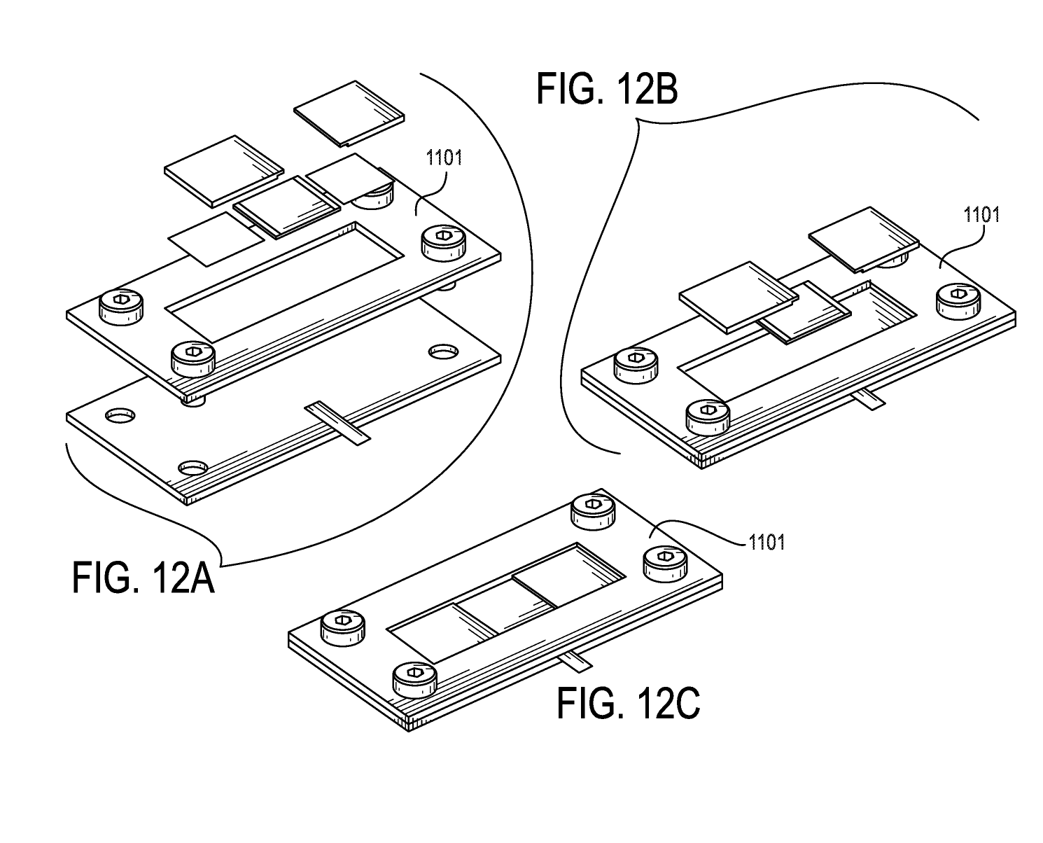

FIG. 12A shows a drawing showing an exemplary exploded view of a of a high temperature solar cell mount with a temporarily top template plate 1101 as an assembly template. FIG. 12B shows an exemplary drawing showing a partially exploded view of a high temperature solar cell mount with a temporarily mounted top template plate 1101 as an assembly template. FIG. 12C shows an exemplary drawing showing an isometric view of a temporarily assembled high temperature solar cell mount with a top template plate 1101 as an assembly template. The top template plate 1101 is removed after the adhesive under the metal block (e.g. a copper metal block) has had enough time to properly set up (dry, cure, etc.). In use, the bottom plate 111 of an assembled high temperature solar cell mount such as that of FIG. 9D can be mounted to any suitable heat sink, such as, for example a copper heat sink. The copper heat sink can be air cooled and/or fluid cooled (e.g. water cooled).

High Temperature Solar Cell Mount with Flat Strips

In another embodiment, a flat strip, typically a copper strip, contacts the surface area of the back surface 134 of solar cell 131, typically the positive terminal of solar cell 131, in place of the flat wire of the embodiments described hereinabove. The flat strip should have a high thermal conductivity, be relatively thin (e.g. between about 0.0001 in and 1.0 in thick), and electrically conductive. The lower end of the range contemplates advancements in materials innovations, for example graphene, which possess the material characteristics that allow for electrical super conductance even at thin thicknesses. It is contemplated that these materials would allow for practical implementation at the lower bound thickness.

Flat wire embodiments are still a viable option, however the flat wire can act as a lever under the solar cell causing bowing of the solar cell and thermally insulating air voids between the solar cell and the first plate 111. Additionally, it is difficult to use electrically conductive and electrically insulating thermal greases where they can interface with one another. In this high temperature solar cell mount with flat strips embodiment, the electrically conductive grease lubricates the upper surface of the strip and the electrically insulating grease lubricates the bottom surface of the strip such that they are not in direct contact. Also, a stronger mechanical pressure can be applied to the solar cell without causing a bowing or deformation of the solar cell.

Another difference is that the upper (typically negative) electrical leads are raised because of the center flat strip (e.g. positive copper strip). The negative leads are mounted on copper strips of about the same thickness dimension as the center flat strip underneath the solar cell 131. This change to the upper electrical leads provides additional electrical contact which can be used for soldering or otherwise wiring the cell mount assemblies into circuits. Also, the magnitude of the pressure fit based on the extent to which the upper leads are bent or machined to interfere with the solar cell when placing can be better controlled over previous embodiments and the new interference fit generates sufficient clamping pressure to securely hold the solar cell in the mount. An interference fit, also known as a press fit or friction fit, is defined as a fastening between two parts which is achieved by friction after the parts are pushed together.

It is contemplated that a relatively wide range of mechanical pressure can be used, such as, for example from just above 0 Nm² to about 20,000,000,000 Nm². In some embodiments, such as has been used in recent implementations, the mechanical pressure exerted by the ends of the first flat lead and a second flat lead respectively against the busbar edges on either side of the solar cell used a mechanical pressure of about between 1×10⁶ N/m² and 20,000×10⁶ N/m².

In another embodiment, the interference fit, also known as a press fit or friction fit, created by the first and second leads on the solar cell busbars is resultant of a deflection in the portion of the leads which interfaces with the solar cell busbars. This portion of the lead is modeled as a moment arm with an effective spring constant which, once deflected, creates a downward force or pressure on the busbar top surface area.

The portions of the first and second flat leads which are present in some embodiments described hereinabove can be glued to their respective strips using an electrically conductive epoxy.

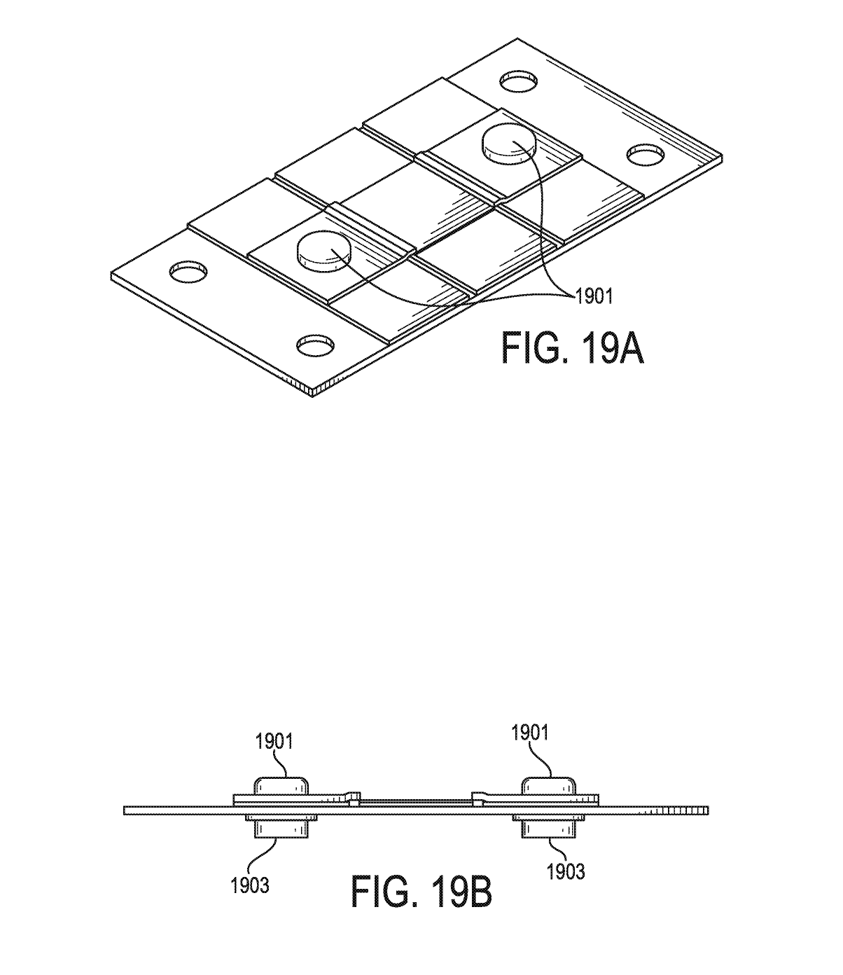

In another embodiment, the first and second flat leads can be fixed to their respective strips using a suitable mechanical means, for example, a bolt or dowel. The bolt can be any suitable type bolt, such as for example, any suitable machine screw. A machine screw can have any suitable head, such as for example, flat head, round head, fillister head, pan head, etc. FIG. 19A shows an isometric view of an exemplary high temperature mount where the flat leads are coupled to the flat strips respectively by fasteners 1901, such as machine screws, held in place by a capture part 1903, such as machine nut. FIG. 19B shows a side view of the high temperature mount of FIG. 19A. While the fasteners of the example include separate capture parts, there can be embodiments where fasteners 1901 sink or thread into a surface to which the high temperature mount is affixed, such as for example, an air or water cooled heatsink.

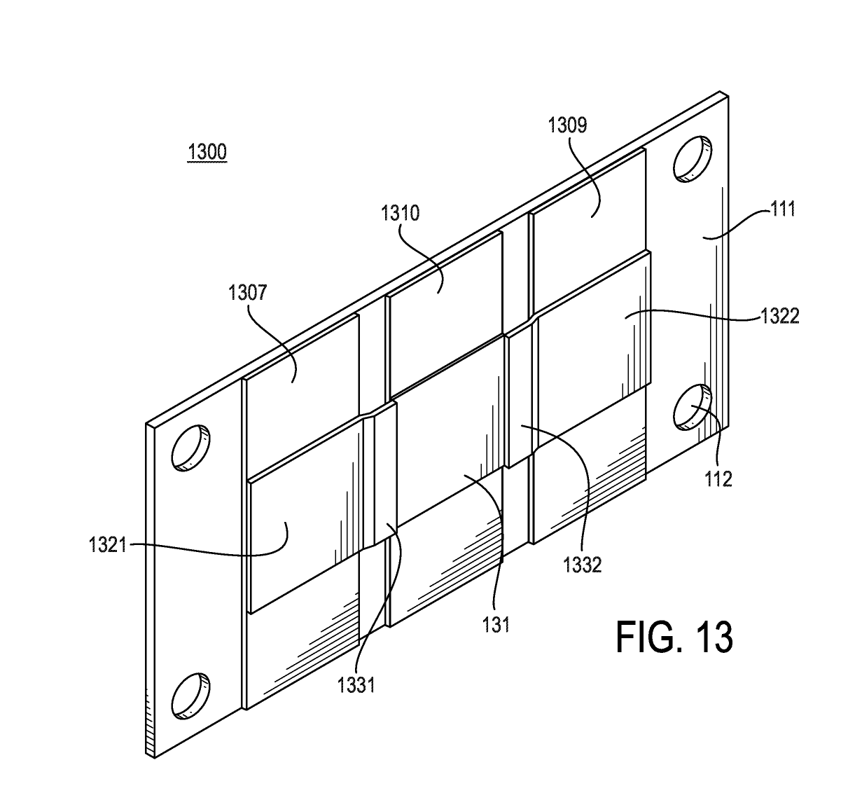

FIG. 13 shows an isometric view of an exemplary high temperature solar cell mount 1300. Solar cell 131 is mounted on center flat strip 1310 defining about a solar cell foot print area over both a plate front surface of plate 111 and center flat strip 1310 by pressure contact. An electrically conductive grease layer can be used between the bottom surface 134 of solar cell 131 and center flat strip 1310. Center flat strip 1310 can be thermally coupled to a plate front surface of first plate 111 by a layer of electrically insulating thermal grease, or by a thermal epoxy, or any other suitable adhesive or glue. First flat strip 1307 and second flat strip 1309 are typically mechanically coupled to the plate front surface of first plate 111 by any suitable glue, adhesive, or epoxy. First flat lead 1321 and second flat lead 1322 can be mechanically coupled to first flat strip 1307 and second flat strip 1309 by any suitable epoxy, typically an electrically conductive adhesive or epoxy. First flat lead 1321 and second flat lead 1322 are mounted on the first flat strip 1307 and second flat strip 1309 respectively oriented in about the flat lead direction 1351.

The interference fit of first flat lead 1331 and second flat lead 1332 with the side buss bars 132 respectively of solar cell 131, provide the electro-mechanical pressure mount of the solar cell 131 onto center flat strip 1310 and first plate 111. Each of the raised ends of the first flat lead and the second flat lead can be mechanically, thermally, and electrically coupled respectively to the busbar edges on either side of the solar cell by the pressure contact.

Flat strip 1307, center flat strip 1310, and second flat strip 1309 are conductive flat strips, such as, for example, as can be made from copper. Other exemplary suitable materials include Pyrolitic Graphite, Graphene, Silver, Gold, Tungsten, and Aluminum. The portions of first flat strip 1307, flat strip 1310, and second flat strip 1309 which in some embodiments extend adjacent to and on either side of first flat lead 1321, second flat lead 1322, and solar cell 131 can provide solder pads for wire connections to first flat lead 1321, second flat lead 1322, and the bottom surface 134 of solar cell 131.

Those skilled in the art will understand that alternative exemplary electrical connection types can be used to electrically couple wires or conductors to the electrical terminals (e.g. flat leads) of the various embodiments of the new high temperature solar cell mount, such as, for example, an electrical adhesive or tape, a tactic bonding, a snap fit connector, a screw and other suitable mechanical connector, a fuse lead or terminal, diode lead or terminal, a printed circuit board, a bread board connection, a wire nut, a pressure fit, a plug, a pin or socket terminal, a clamp, a weld, and/or a stress fit.

Most commonly, the metallization of bottom surface 134 of solar cell 131 is the positive electrical terminal of the solar cell 131. The solar cell electrical contract strips 132 (side busbars of solar cell 131) are most commonly the corresponding negative electrical terminal of solar cell 131. Therefore when mounted in a high temperature solar cell mount 1300 with flat strips, either extended side of the center flat strip 1310 can provide the positive electrical terminal for solar cell 131. Similarly, either or both of the first flat strip 1307 and/or the second flat strip 1309 can provide the negative electrical terminal for solar cell 131. Should the opposite polarity be manufactured in a suitable solar cell (e.g. the back metallization as the negative terminal and the edge buss bar as the positive terminal), the polarity of the connections described hereinabove can be reversed.

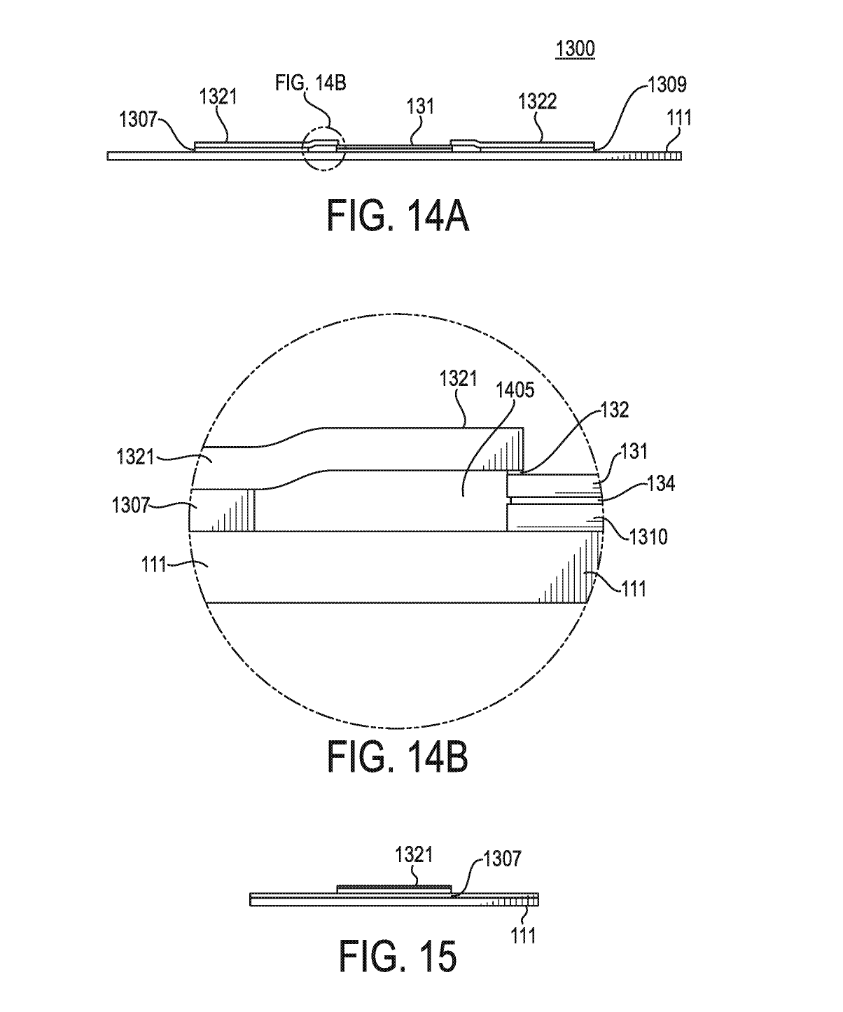

FIG. 14A shows a side view of the solar cell mount 1300 of FIG. 13. FIG. 15 shows an end view of the solar cell mount of FIG. 14A.

FIG. 14B shows a partial section view of the solar cell mount of FIG. 14A. First flat lead 1321 is mechanically and electrically coupled to first flat strip 1307. The end of first flat lead 1321 overlaps and makes mechanical and electrical contact with solar cell electrical contract strip 132 (a side busbar of solar cell 131). The back surface 134 metallization of solar cell 131 makes mechanical and electrical contact with center flat strip 1310. First flat strip 1307, second flat strip 1309, and center flat strip 1310 are both mechanically coupled to first plate 111.

Mechanical coupling and mechanical and electrical coupling: It is understood that mechanical coupling can be by a pressure contact, such as for example, the mechanical and electrical coupling of the end of first flat lead 1321 overlaps and makes mechanical and electrical contact with solar cell electrical contract strip 132 of solar cell 131 which holds solar cell 131 in place on the solar cell mount 1300. Mechanical coupling can also be accomplished by any suitable glue, adhesive, or epoxy, such as can be used to mechanically couple first flat strip 1307 and center flat strip 1310 to first plate 111.

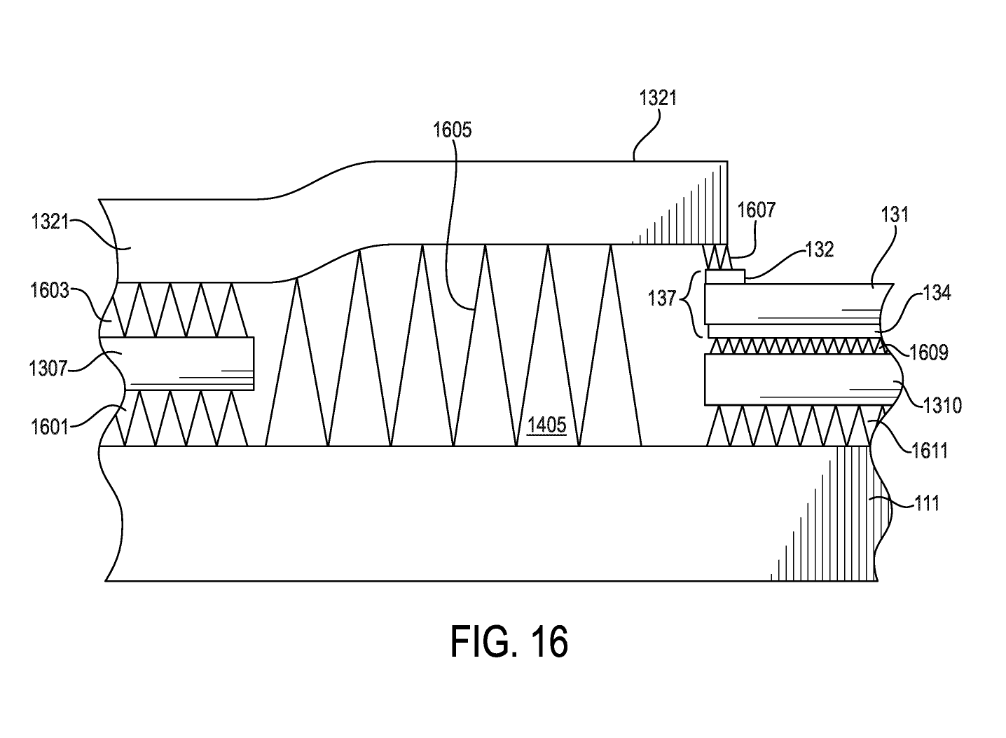

FIG. 16 shows an exploded view of one exemplary embodiment of a solar cell mount 1300 which when assembled as per FIG. 16 results in the solar cell mount of FIG. 14A. In the exemplary embodiment of FIG. 16, first flat strip 1307 is mechanically coupled to first plate 111 by any suitable thermal epoxy 1601. First flat lead 1321 is mechanically and electrically coupled to first flat strip 1307 by any suitable electrically conductive thermal epoxy 1603. Center flat strip 1310 is mechanically coupled to first plate 111 by any suitable electrically insulating thermal grease 1611. The back surface 134 metallization of solar cell 131 is mechanically and electrically coupled to center flat strip 1310 using any suitable electrically conductive thermal grease 1609. The end of first flat lead 1321 (typically a raised end by an S shape, notch L shape, or any other suitable machining or bend). The machining or bend of the flat leads accounts for the thickness of the solar cell to allow for a pressure fit, where the electrically conductive material typically copper, and typically in the thickness range of 0.005″-0.5″) of the end of the flat lead overlaps solar cell electrical contact strip 132 of solar cell 131 to make electrical contact with solar cell electrical contact strip 132 typically by pressure contact alone, however the contact could also include any suitable compound, such as, for example, an electrically conductive thermal grease 1607 disposed therebetween. Void 1405 can be left empty and open to air or can be filled with any electrically insulating material such as, for example, and electrically insulating thermal grease 1605. It is only important that a conductor or conductive grease not cause an electrical short circuit along the side 137 of solar cell 131 by inadvertently electrically coupling solar cell electrical contact strip 132 to the bottom surface 134 metallization layer of the solar cell 131.

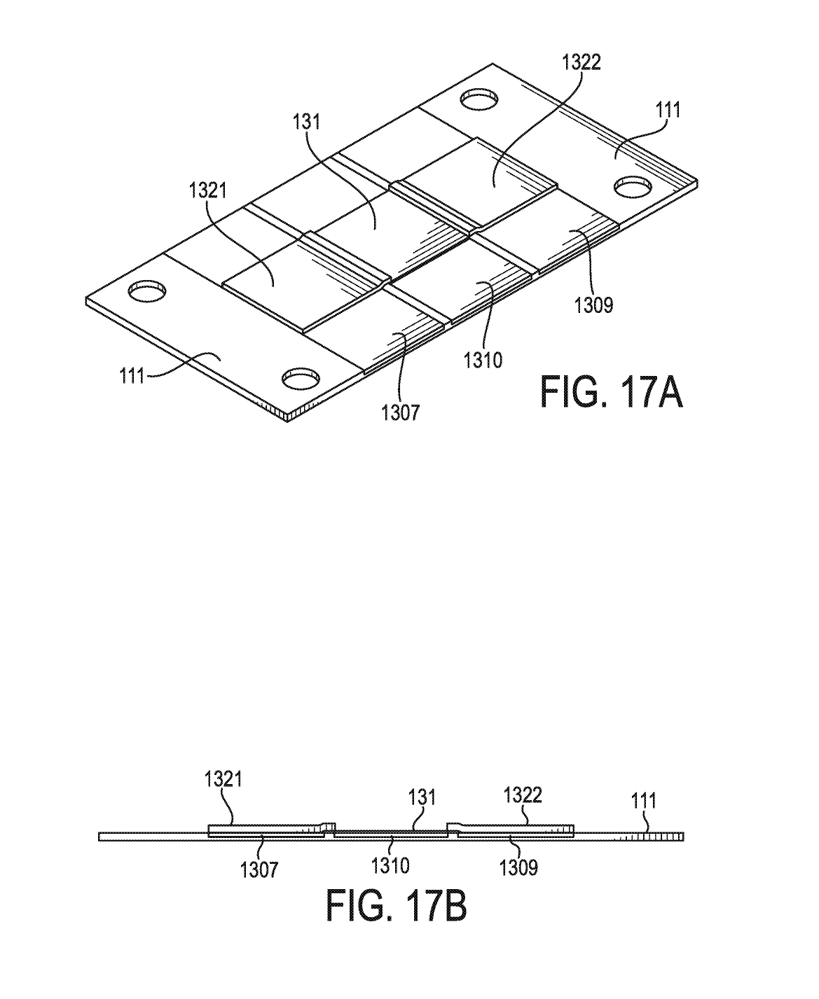

In some embodiments, the first flat strip 1307, second flat strip 1309, and center flat strip 1310 can be embedded in part or in whole into the plate 111. FIG. 17A shows an isometric view of an exemplary high temperature solar cell mount with flat strips embedded in the plate. FIG. 17B shows a side view of the solar cell mount of FIG. 17A. The bend or machining of the flat lead 1321 and flat lead 1322 accomplish the same interference fit between the ends of the flat lead 1321 and flat lead 1322 and the respective side buss bars of solar cell 131 as described hereinabove.

In another embodiment, a flat strip, typically a copper strip, contacts the surface area of the back surface 134 of solar cell 131, typically the positive terminal of solar cell 131, in place of the flat wire of the embodiments described hereinabove. The flat strip should have a high thermal conductivity, high electrical conductivity, and be relatively thick (up to 1.0 in). The strip includes holes to allow for the flow of fluids or air to improve the thermal cooling characteristics of the high temperature mount.

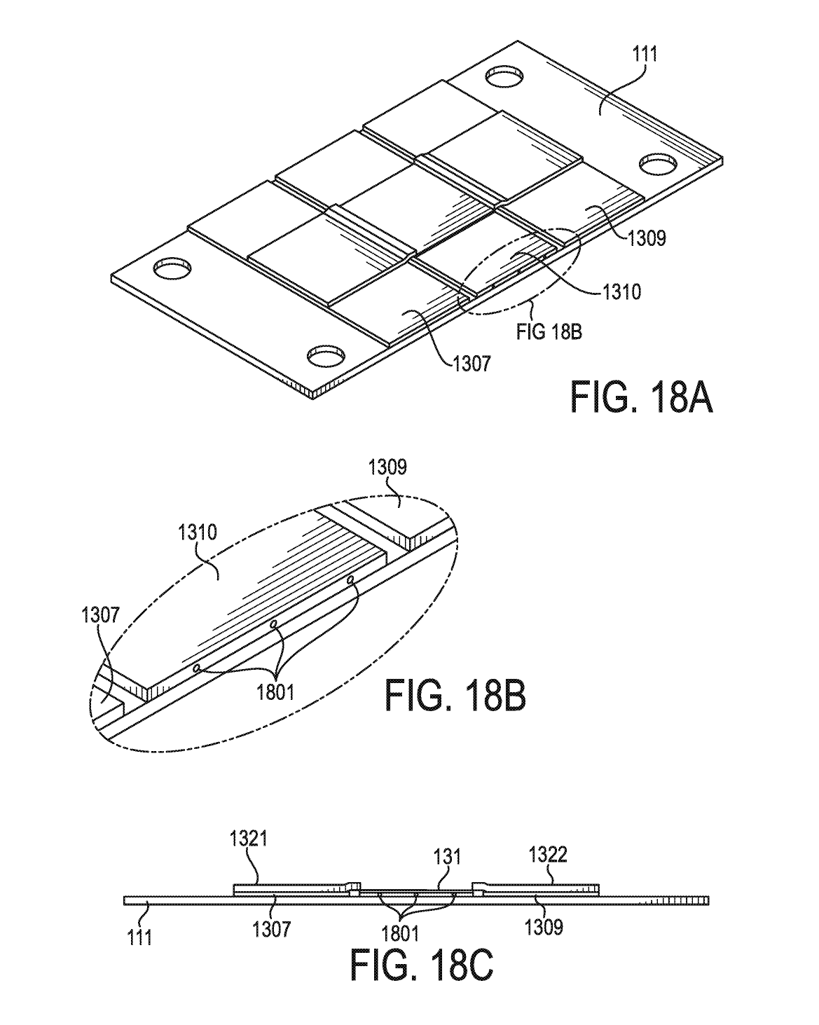

FIG. 18A shows one such exemplary embodiment of a high temperature solar cell mount with flat strips with holes 1801 for a cooling gas or fluid to flow through the flat center strip 1310. FIG. 18B shows a partial magnified view of the high temperature mount of FIG. 18A. FIG. 18C shows a side view of the high temperature mount of FIG. 18A. The holes 1801 typically extend from one end of the center flat strip to the other end (not visible in FIG. 18A). Those skilled in the art will appreciate that the holes could also open to the top surface of the ends of the center flat strip and bend within to form gas or fluid passages through the center flat strip. Also, those skilled in the art will appreciate that any suitable connection technique, device or connector can be used to couple a gas or fluid flow to and from the holes 1801 (not shown in FIG. 18A).

### Example

In one exemplary implementation, an alumina or aluminum nitride flat plate 111 (typically, the bottom plate) has a thickness of about 0.027″. First flat strip 1307, second flat strip 1309, and center flat strip 1310 are made from a rectangular copper strip of between about 0.01″ and 0.02″. First flat lead 1321 and second flat lead 1322 are made from copper bars having a thickness of about 0.027″ and with a bent or machined “S” bend to provide an interference fit with the solar cell which provides a sufficient clamping pressure to hold the solar cell in the solar cell mount by the raised ends of first flat lead 1321 and second flat lead 1322 with solar cell electrical contact strip 131 and electrical contact strip 132 respectively. First flat strip 1307 is mechanically coupled to first plate 111 by thermal epoxy 1601 J-B Weld Twin Tube, available from J-B Weld of Sulphur Springs, Tex. First flat lead 1321 is mechanically and electrically coupled to first flat strip 1307 by electrically conductive thermal epoxy 1603 Chemtronics CW2400, available from Chemtronics of Kennesaw, Ga. Center flat strip 1310 is mechanically coupled to first plate 111 by an electrically insulating thermal grease 1611 Shin Etsu MicroSi G751, available from Shin-Etsu MicroSi, Inc. of Phoenix, Ariz. The back surface 134 metallization of solar cell 131 is mechanically and electrically coupled to center flat strip 1310 using electrically conductive thermal grease 1609. Chemtronics CW2400, available from Chemtronics of Kennesaw, Ga. The raised end of first flat lead 1321 overlaps solar cell electrical contact strip 132 of solar cell 131 and makes electrical contact with solar cell electrical contact strip 132 through an electrically conductive thermal grease 1607 disposed therebetween Chemtronics CW2400, available from Chemtronics of Kennesaw, Ga. Void 1405 can be left empty and open to air of can be filled with any electrically insulating material such as, for example, and electrically insulating thermal grease 1605 name, Shin Etsu MicroSi G751, available from Shin-Etsu MicroSi, Inc. of Phoenix, Ariz.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

What is claimed is:

1. A high temperature electro-mechanical pressure mount for a solar cell having a solar cell foot print area, a back surface metallization, and at least two busbar edges on either side of said solar cell comprising:
a plate electrically insulating and thermally conductive having a plate front surface and a solar cell foot print area;
a center flat strip disposed on or in said plate front surface at about said solar cell foot print area and extending outwardly from either side of said solar cell foot print area in a flat strip direction, said center flat strip electrically conductive and thermally coupled to said plate front surface;
a first flat strip and a second flat strip disposed on or in said plate front surface on either side of said solar cell foot print area respectively and extending beyond said solar cell foot print area in said flat strip direction, both of said first flat strip and a second flat strip thermally and mechanically coupled to said plate front surface; and
a first flat lead and a second flat lead disposed on and about perpendicular to said first flat strip and said second flat strip respectively, such that each end of said first flat lead and a second flat lead mechanically, thermally, and electrically couple respectively to the busbar edges on either side of the solar cell disposed over about a solar cell footprint area and hold the solar cell in the high temperature electro-mechanical pressure mount by a mechanical pressure exerted by the ends of said first flat lead and a second flat lead respectively against the busbar edges on either side of the solar cell.

2. The high temperature electro-mechanical pressure mount of claim 1, wherein said mechanical pressure exerted by the ends of said first flat lead and a second flat lead respectively against the busbar edges on either side of the solar cell comprises a mechanical pressure between about 1×10⁶ N/m² and 20,000×10⁶ N/m².

3. The high temperature electro-mechanical pressure mount of claim 1, wherein said first flat strip and said second flat strip are thermally and mechanically coupled to said plate front surface by an epoxy.

4. The high temperature electro-mechanical pressure mount of claim 1, wherein said first flat lead and a second flat lead are thermally and electrically coupled to said first flat strip and said second flat strip by an epoxy.

5. The high temperature electro-mechanical pressure mount of claim 1, wherein said first flat lead and a second flat lead are mechanically coupled to said first flat strip and said second flat strip by a fastener.

6. The high temperature electro-mechanical pressure mount of claim 1, wherein said center flat strip is thermally coupled to said plate by a thermal compound or a thermal epoxy.

7. The high temperature electro-mechanical pressure mount of claim 6, wherein said thermal compound comprises a thermal grease.

8. The high temperature electro-mechanical pressure mount of claim 1, wherein at least one of said first flat lead and said second flat lead comprise an S shape to provide a raised end.

9. The high temperature electro-mechanical pressure mount of claim 8, wherein each raised end of said first flat lead and said second flat lead are mechanically, thermally, and electrically coupled respectively to the busbar edges on either side of the solar cell by a pressure contact.

10. The high temperature electro-mechanical pressure mount of claim 1, wherein said center flat strip provides a positive electrical terminal of a solar cell, and either or both of said first flat lead and said second flat lead provide a negative terminal of the solar cell.

11. The high temperature electro-mechanical pressure mount of claim 1, wherein said center flat strip, said first flat strip and said second flat strip comprise copper.

12. The high temperature electro-mechanical pressure mount of claim 1, wherein said first flat lead and said second flat lead comprise copper.

13. The high temperature electro-mechanical pressure mount of claim 1, wherein said first flat lead and said second flat lead comprise an S bend.

14. The high temperature electro-mechanical pressure mount of claim 1, wherein said center flat strip comprises at least one or more holes to provide a path within said center flat strip for a gas flow or a fluid flow.

15. A high temperature electro-mechanical pressure mount for a solar cell having a solar cell foot print area, a back surface metallization, and at least two busbar edges on either side of said solar cell comprising:
a plate electrically insulating and thermally conductive having a plate front surface and a solar cell foot print area;
a center flat strip disposed over said solar cell foot print area and extending outward from either side of said solar cell foot print area in a flat strip direction, said center flat strip electrically conductive and thermally coupled to said plate front surface by a thermal compound or a thermal epoxy;
a first flat strip and a second flat strip disposed on either side of said solar cell foot print area respectively, both of said first flat strip and a second flat strip thermally and mechanically coupled to said plate front surface by an epoxy;
a first flat lead and a second flat lead disposed on and about perpendicular to said first flat strip and a second flat strip respectively, each raised end of said first flat lead and a second flat lead mechanically, thermally, and electrically couples respectively to the busbar edges on either side of the solar cell disposed over about a solar cell footprint area;
wherein said first flat lead and second flat lead hold a solar cell back surface metallization of the solar cell in a mechanical and an electrical contact with said center flat strip by an electro-mechanical pressure mount caused by mechanical pressure of each raised end of said first flat lead and a second flat lead mechanically against each of a pair of side busbars of the solar cell respectively; and
wherein said first flat strip provides a first electrical terminal of said high temperature electro-mechanical pressure mount, the first electrical terminal electrically coupled to the back surface metallization of the solar cell, and said first flat lead and a second flat lead provide a second electrical terminal of said high temperature electro-mechanical pressure mount, the second electrical terminal electrically coupled to at least two busbar edges on either side of said solar cell.

16. A method for mounting a solar cell in a high temperature electro-mechanical pressure mount comprising the steps of:
providing an electrically insulating and thermally conductive plate having a plate front surface and a solar cell foot print area;
mounting a center flat strip, a first strip, and a second strip to said plate front surface, said first strip and said second strip separated from and adjacent to said center flat strip, all of said center flat strip, said first strip, and said second strip oriented in about a flat strip direction on said plate front surface;
applying a thermal compound to said center flat strip over about said solar cell foot print area;
setting a back surface metallized layer of a solar cell into said thermal compound;
applying an electrically conductive thermal compound to at least two busbar edges on either side of a light receiving surface of the solar cell; and
mounting mechanically and electrically a first flat lead and a second flat lead over said first strip, and a second strip respectively, each in a direction about perpendicular to said flat strip direction where an end of each flat lead overlaps and couples to each of the busbar edges respectively, by at least in part pressing on the busbar edges through said electrically conductive thermal compound.

17. The method of claim 16, wherein said step of mounting a center flat strip, a first strip, and a second strip comprises mounting a center flat strip, a first strip, and a second strip to said plate front surface by use of an epoxy.

18. The method of claim 16, wherein said step of mounting mechanically and electrically a first flat lead and a second flat lead over said first strip comprises mounting mechanically and electrically a first flat lead and a second flat lead over said first strip, and a second strip respectively by use of an epoxy.
